(19) United States
(12) Patent Application Publication
(10) Pub. No.: US 2025/0368879 A1
(43) Pub. Date: Dec. 4, 2025

(54) Thermal Interface Material

(71) Applicant: Polytronics Technology Corp., HSINCHU (TW)

(72) Inventors: HSIU-CHE YEN, Taoyuan City (TW); CHINGTING CHIU, Taoyuan City (TW); YUNG-HSIEN CHANG, Douliu City (TW); Chia-Yuan Lee, Hsinchu City (TW); CHENG-YU TUNG, Tainan City (TW); CHEN-NAN LIU, Changhua County (TW); Yao-Te Chang, Yunlin County (TW)

(21) Appl. No.: 18/798,086

(22) Filed: Aug. 8, 2024

(30) Foreign Application Priority Data
May 31, 2024 (TW) 113120224

(51) Int. Cl. C09K 5/06; H01L 23/373

(52) U.S. Cl. CPC C09K 5/063; H01L 23/3737

(57) ABSTRACT

A thermal interface material includes a thermally melting material and an inner filler. The thermally melting material includes an olefin-acrylate copolymer having a melt flow index higher than 110 g/10 min. The inner filler has a plurality of thermally conductive fillers and a highly dispersible filler. The total volume of the thermal interface material is calculated as 100%, with the olefin-acrylate copolymer accounting for 25% to 35%, and the thermally conductive fillers and the highly dispersible filler accounting for 65% to 75%.

### BACKGROUND OF THE INVENTION

### (1) Field of the Invention

The present application relates to a thermal interface material, and more specifically, to a thermal interface material that is highly durable and effective at conducting heat.

### (2) Description of the Related Art

It is well-known that electronic devices (e.g., LEDs or other semiconductor devices) generate heat during operation, and their performance is compromised once the accumulation of heat reaches a certain threshold. Therefore, heat sinks (e.g., fin-type heat sinks) are often installed on their surfaces to reduce the accumulation of heat. In order to reduce thermal resistance at the contact interface between the electronic device and the heat sink, a thermal interface material can be placed between them.

Conventionally, there are many types of thermal interface material (TIM), including thermally conductive grease, thermally conductive gel, thermally conductive pad, phase change material-based type, and so on. However, these thermal interface materials often include silicone-containing resins as the basic constituents in the matrix. This may lead to the leakage of silicone oil during operation. Additionally, the issue of operable time arises when it comes to phase change material. The operable time refers to the number of times the thermal interface material can withstand temperature shocks without being damaged or flowing out. The melting point of a phase change material is often below 70° C. When the environmental temperature is higher than its melting point, the phase change material changes into the liquid phase, thereby flowing out from the interface between the electronic device and the heat sink. In another case, when the environmental temperature approaches its melting point, the phase change material is softened and prone to deformation, leading to the damage of its structure. Even though the melting point of it can be adjusted to be higher, the aforementioned issue of high flowability still exists when the temperature approaches or exceeds its melting point. More importantly, excellent thermally conductive characteristics need to be taken into account when addressing the above issues.

For instance, to ensure good thermal conductivity, the thermal interface material conventionally includes two thermally conductive fillers with different mean or median diameters (referred to as “first thermally conductive filler” and “second thermally conductive filler” hereinafter), thereby increasing the filling ratio. However, as seen in the microscopic view, either the first thermally conductive filler or the second thermally conductive filler inevitably consists of particles with various sizes, even if selected based on mean or median diameter. As a result, the filling ratio is usually less than expected, which also affects the overall structure and thermal conductivity properties of the thermal interface material. To address the aforementioned deficiencies, the thermal interface material may further include various additives (e.g., organic solvents, cross-linking agents, or other compounds) to enhance its overall performance. From the above, it is understood that precise control over the composition of thermally conductive fillers in the thermal interface material is challenging, and the formulation design of the thermal interface material is highly complex.

### SUMMARY OF THE INVENTION

In accordance with an aspect of the present invention, a thermal interface material includes a thermally melting material and an inner filler. The thermally melting material includes an olefin-acrylate copolymer. The olefin-acrylate copolymer has a melt flow index higher than 110 g/10 min. The total volume of the thermal interface material is calculated as 100%, and the olefin-acrylate copolymer accounts for 25% to 35%. The inner filler has a plurality of thermally conductive fillers and a highly dispersible filler. The total volume of the thermal interface material is calculated as 100%, and the thermally conductive fillers and the highly dispersible filler together account for 65% to 75%.

In an embodiment, the olefin-acrylate copolymer has a melting point lower than 70° C. and the melt flow index ranging from 110 g/10 min to 500 g/10 min. The olefin-acrylate copolymer is represented by a formula (I):

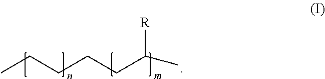

R is selected from the group consisting of COOCH₃, COOCH₅, COOC₄H₉, and COOC₆H₁₃. m ranges from 500 to 3000, and n ranges from 300 to 2000. m is larger than n.

In an embodiment, the total volume of the inner filler is calculated as 100%, and the highly dispersible filler accounts for 1% to 15%. The highly dispersible filler has a maximum diameter smaller than 1.5 μm.

In an embodiment, the highly dispersible filler includes a titanium-containing oxide selected from the group consisting of rutile titanium dioxide and unavoidable impurities. The total weight of the titanium-containing oxide is calculated as 100%, and the rutile titanium dioxide accounts for over 90%.

In an embodiment, the thermally conductive fillers include a first thermally conductive filler and a second thermally conductive filler. The first thermally conductive filler has a maximum diameter smaller than 10 μm. The second thermally conductive filler has a maximum diameter smaller than 50 μm.

In an embodiment, the maximum diameter of the first thermally conductive filler ranges from 8 μm to 10 μm. The total volume of the inner filler is calculated as 100%, and the first thermally conductive filler ranges from 31% to 42%. The maximum diameter of the second thermally conductive filler ranges from 40 μm to 50 μm. The total volume of the inner filler is calculated as 100%, and the second thermally conductive filler ranges from 54% to 62%.

In an embodiment, the first thermally conductive filler and the second thermally conductive filler are selected from the group consisting of aluminum nitride, aluminum oxide, boron nitride, silicon carbide, and magnesium oxide.

In an embodiment, the thermally conductive fillers have maximum diameters smaller than 50 μm, and the highly dispersible filler has a maximum diameter smaller than 1.5 μm. The thermal interface material has a thickness ranging from 0.05 mm to 0.21 mm, with a thermal resistance ranging from 0.07 cm²·° C./W to 0.5 cm²·° C./W and a thermal conductivity ranging from 3 W/m·K to 81 W/m·K.

In an embodiment, the thickness of the thermal interface material ranges from 0.06 mm to 0.15 mm, with the thermal resistance ranging from 0.08 cm²·° C./W to 0.24 cm²·° C./W and the thermal conductivity ranging from 11.24 W/m·K to 80.08 W/m·K.

In an embodiment, the thermal interface material has a thermal resistance ranging from 0.08 cm²·° C./W to 0.24 cm²·° C./W and a thermal conductivity ranging from 11.24 W/m·K to 80.08 W/m·K after a first weather-resistance test. The first weather-resistance test includes placing the thermal interface material at a temperature of 85° C. and a relative humidity of 85% for 500 hours.

In an embodiment, the thermal interface material has a thermal resistance ranging from 0.1 cm²·° C./W to 0.31 cm²·° C./W and a thermal conductivity ranging from 5.62 W/m·K to 66.4 W/m·K after a second weather-resistance test. The second weather-resistance test includes placing the thermal interface material at a temperature of 125° C. for 500 hours.

In an embodiment, the thermal interface material has a thickness greater than 0.1 mm, and an operable time for the thermal interface material is at least two, wherein the operable time is defined as the number of times the thermal interface material can be tested according to ASTM D5470 without being damaged.

In an embodiment, the thickness of the thermal interface material is greater than 0.15 mm, and the operable time for the thermal interface material is at least five.

In accordance with an aspect of the present invention, an electronic apparatus includes a heat sink, an electronic device, and a thermal interface material as previously mentioned. The heat sink has a front side and a back side opposite to the front side. The electronic device has a front side and a back side opposite to the front side. The back side of the electronic device faces the back side of the heat sink. The thermal interface material is disposed between the heat sink and the electronic device. The thermal interface material attaches to the back side of the heat sink and the back side of the electronic device.

In an embodiment, the olefin-acrylate copolymer has a melting point lower than 70° C. and the melt flow index ranging from 110 g/10 min to 500 g/10 min, and the olefin-acrylate copolymer is represented by a formula (I):

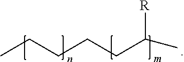

R is selected from the group consisting of COOCH₃, COOC₂H₅, COOC₄H₉, and COOC₆H₁₃. m ranges from 500 to 3000, and n ranges from 300 to 2000. m is larger than n.

In an embodiment, in the thermal interface material of the electronic apparatus, the highly dispersible filler includes a titanium-containing oxide selected from the group consisting of rutile titanium dioxide and unavoidable impurities, wherein the total weight of the titanium-containing oxide is calculated as 100%, and the rutile titanium dioxide accounts for over 90%; the total volume of the inner filler is calculated as 100%, and the highly dispersible filler accounts for 1% to 15%; and the highly dispersible filler has a maximum diameter smaller than 1.5 μm.

In an embodiment, in the electronic apparatus, the thermally conductive fillers of the thermal interface material include a first thermally conductive filler and a second thermally conductive filler. A maximum diameter of the first thermally conductive filler ranges from 8 μm to 10 μm. The total volume of the inner filler is calculated as 100%, and the first thermally conductive filler ranges from 31% to 42%. A maximum diameter of the second thermally conductive filler ranges from 40 μm to 50 μm. The total volume of the inner filler is calculated as 100%, and the second thermally conductive filler ranges from 54% to 62%.

In an embodiment, the first thermally conductive filler and the second thermally conductive filler are selected from the group consisting of aluminum nitride, aluminum oxide, boron nitride, silicon carbide, and magnesium oxide.

In an embodiment, in the thermal interface material of the electronic apparatus, the thermally conductive fillers have maximum diameters smaller than 50 μm, and the highly dispersible filler has a maximum diameter smaller than 1.5 μm. The thermal interface material has a thickness ranging from 0.05 mm to 0.21 mm, with a thermal resistance ranging from 0.07 cm²·° C./W to 0.5 cm²·° C./W and a thermal conductivity ranging from 3 W/m·K to 81 W/m·K

In an embodiment, the thermal interface material has a thickness greater than 0.1 mm, and an operable time for the thermal interface material is at least two. The operable time is defined as the number of times the thermal interface material can be tested according to ASTM D5470 without being damaged.

### BRIEF DESCRIPTION OF THE DRAWINGS

The present application will be described according to the appended drawings in which:

FIG. 1 shows a cross-sectional view of a thermal interface material;

FIG. 2 shows a cross-sectional view of a thermal interface material in accordance with the present invention; and

FIG. 3 shows a cross-sectional view of an electronic apparatus in accordance with the present invention.

### DETAILED DESCRIPTION OF THE INVENTION

The making and using of the presently preferred illustrative embodiments are discussed in detail below. It should be appreciated, however, that the present application provides many applicable inventive concepts that can be embodied in a wide variety of specific contexts. The specific illustrative embodiments discussed are merely illustrative of specific ways to make and use the invention, and do not limit the scope of the invention.

The present invention introduces a polymer melting material (PMM), also referred to as thermally melting material, into a thermal interface material. The thermally melting material has low flowability even at a temperature above its melting point, thereby maintaining the stability of the entire structure. In other words, the thermally melting material can help rapidly reduce the temperature of its target device through its phase change process, and, in the meantime, its durability (e.g., the aforementioned operable time) is not compromised by structural instability during the phase change process. Furthermore, the flowability of the thermally melting material is not too low to smoothly adhere uneven surfaces. To ensure good thermal conductivity of the thermal interface material, the present invention further includes various fillers. Since the thermally melting material possesses stable physical/chemical properties and has good compatibility with the fillers, there is no need to add other additives to the thermal interface material.

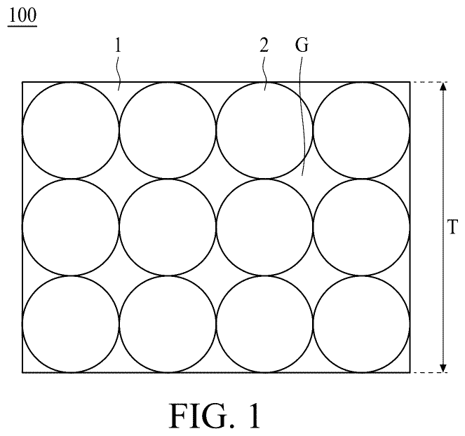

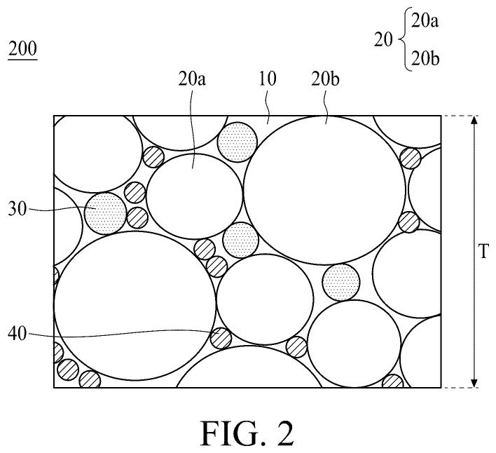

Regarding the various fillers, please continue to refer to FIG. 1 and FIG. 2.

FIG. 1 shows a cross-sectional view of a thermal interface material 100. The thermal interface material 100 includes a polymer 1 and a thermally conductive filler 2. The thermal interface material 100 is a composite material, with the polymer 1 serving as its matrix and the thermally conductive filler 2 as its reinforcement. As shown in FIG. 1, the thermally conductive filler 2 substantially consists of a plurality of particles. Ideally, one would expect all particles in the thermally conductive filler 2 to be the same size in order to achieve structural consistency and facilitate the adjustment of composition ratios. If gaps G still exist between particles, they can be filled with a smaller thermally conductive filler, which consists of a plurality of smaller particles of the same size. However, it is impossible for the thermally conductive filler 2 to have completely uniform sizes during production. This creates the gaps G with various sizes and make the thermal resistance at the contact interface difficult to control, affecting the overall thermally conductive performance of the thermal interface material 100.

Therefore, the present invention additionally incorporates a filler with high dispersibility to address the issue of thermal contact resistance and simplify the composition. The production of the thermal interface material of the present invention does not require wet processing, and thus, organic solvents are not used for dissolving polymers, significantly reducing environmental pollution. In the meantime, the present invention does not include cross-linking agents or silicone-containing resins. Please refer to FIG. 2.

FIG. 2 shows a cross-sectional view of a thermal interface material 200 in accordance with the present invention. The thermal interface material 200 includes a thermally melting material 10 and an inner filler. The inner filler has a first thermally conductive filler 20, a second thermally conductive filler 30, and a highly dispersible filler 40. As described above, each filler consists of a plurality of particles, with the particles varying in size. For example, the first thermally conductive filler 20 has small particles 20a with a smaller diameter, and large particles 20b with a larger diameter. This results in gaps of varying sizes in the first thermally conductive filler 20. Similarly, the second thermally conductive filler 30 and the highly dispersible filler 40 are also composed of particles, thus exhibiting the size variation. For simplification and clarity, their particles (i.e., particles of the second thermally conductive filler 30, or particles of the highly dispersible filler 40) are illustrated in the same or similar size herein. The present invention finds that the issue of thermal contact resistance between particles is primarily influenced by the largest particles with the maximum diameter. If the adjustment of the filler ratios is based on the mean or median diameter, an excessive amount of particles with the maximum diameter cannot be accommodated in the gaps, leading to unpredictable performance of the thermal interface material 200. Accordingly, the maximum diameter is used as an index for all fillers to determine the filler ratios in the present invention. In the thermal interface material 200 of the present invention, the first thermally conductive filler 20 and the second thermally conductive filler 30 having different maximum diameters are dispersed within the thermally melting material 10, and the remaining small gaps are filled with the highly dispersible filler 40. The details of the thermally melting material 10 and the inner are described below.

The thermally melting material 10 includes an olefin-acrylate copolymer. The olefin-acrylate copolymer has a melting point lower than 70° C. and the melt flow index ranging from 110 g/10 min to 500 g/10 min. The thermally melting material 10 of the present invention does not flow out from the interface under high temperature, and it is not too rigid, allowing it to adhere closely to and fill the gaps at the interface. For example, if the melt flow index is lower than 110 g/10 min, the flowability of the thermally melting material 10 is too low. In this case, the structure of the thermally melting material 10 is excessively stable, hindering the thermal interface material 200 from fully filling the gaps at the interface between two devices, leading to high thermal contact resistance between them. If the melt flow index is higher than 500 g/10 min, there are issues such as structural damage and flow-out from the interface, as previously mentioned. In one embodiment, the melt flow index ranges from 110 g/10 min to 500 g/10 min, such as 110 g/10 min, 150 g/10 min, 170 g/10 min, 200 g/10 min, 290 g/10 min, 320 g/10 min, 350 g/10 min, 400 g/10 min, 450 g/10 min, or 500 g/10 min. Preferably, the melt flow index ranges from 110 g/10 min to 150 g/10 min. If the maximum of the melt flow index is lower than 150 g/10 min, the thermal interface material 200 can be made ultra-thin (e.g., 0.06 mm in thickness) and remain unaffected by high temperature, with no excessive deformation or damage.

In addition, the olefin-acrylate copolymer is represented by a formula (I):

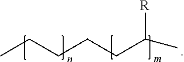

R is selected from the group consisting of COOCH₃, COOC₂H₅, COOC₄H₉, and COOC₆H₁₃. m ranges from 500 to 3000, and n ranges from 300 to 2000. m is larger than n. The total volume of the thermal interface material 200 is calculated as 100%, and the olefin-acrylate copolymer accounts for 25% to 35%, such as 25%, 26%, 27%, 28%, 29%, 30%, 31%, 32%, 33%, 34%, or 35%. In the olefin-acrylate copolymer, the —OR group of its acrylate repeating unit is able to chemically bond to the surface of the inorganic material. In other words, the olefin-acrylate copolymer enhances adhesion between the thermal interface material 200 and metal surfaces. Moreover, the olefin-acrylate copolymer facilitates the molding of the thermal interface material 200. Overall, the olefin-acrylate copolymer exhibits superior performance compared to the silane compounds typically used.

As for the inner filler, it includes the thermally conductive fillers (e.g., the first thermally conductive filler 20 and the second thermally conductive filler 30) and the highly dispersible filler 40. The first thermally conductive filler 20 and the second thermally conductive filler 30 are selected from the group consisting of aluminum nitride, aluminum oxide, boron nitride, silicon carbide, and magnesium oxide. The highly dispersible filler 40 includes a titanium-containing oxide, such as highly purified titanium dioxide in a specific crystal structure. The thermal conductivity of the titanium-containing oxide is lower than that of the first thermally conductive filler 20 and the second thermally conductive filler 30, so its usage needs to be carefully controlled to avoid increasing thermal contact resistance. More specifically, the titanium-containing oxide is selected from the group consisting of rutile titanium dioxide and unavoidable impurities. The unavoidable impurities includes trace elements and/or other titanium dioxides with different crystal structures, such as anatase titanium dioxide and brookite titanium dioxide. The total weight of the titanium-containing oxide is calculated as 100%, and the rutile titanium dioxide accounts for over 90%. Preferably, the rutile titanium dioxide accounts for over 98%. Optimally, the rutile titanium dioxide accounts for over 99%. The highly dispersible filler 40 not only reduces the thermal contact resistance between the particles but also facilitates the blending and molding of the materials. Excluding the highly dispersible filler 40 makes it difficult to blend and mold the thermally melting material 10 with the first thermally conductive filler 20 and the second thermally conductive filler 30 into the desired shape. The total volume of the thermal interface material 200 is calculated as 100%, while the first thermally conductive filler 20, the second thermally conductive filler 30, and the highly dispersible filler 40 together account for 65% to 75%, such as 65%, 66%, 67%, 68%, 69%, 70%, 71%, 72%, 73%, 74%, or 75%.

As previously mentioned, the maximum diameter serves as the criterion for determining filler ratios in the present invention. The details are described as follows. The first thermally conductive filler 20 consists of a plurality of particles, and the maximum diameter of these particles ranges from 8 μm to 10 μm, such as 8 μm, 8.2 μm, 8.4 μm, 8.7 μm, 9.1 μm, 9.5 μm, or 10 μm. The second thermally conductive filler 30 consists of a plurality of particles, and the maximum diameter of these particles ranges 40 μm to 50 μm, such as 40 μm, 41.5 μm, 43.6 μm, 45.7 μm, 47.5 μm, 49.6 μm, or 50 μm. The highly dispersible filler 40 consists of a plurality of particles, and the maximum diameter of these particles is smaller than 1.5 μm, ranging from 0.8 μm to 1.5 μm. In one embodiment, the maximum diameter of the highly dispersible filler 40 may be 0.8 μm, 0.95 μm, 1.1 μm, 1.26 μm, 1.32 μm, 1.45 μm, or 1.5 μm. As for the ratio of each filler, the details are described as follows. The total volume of the inner filler is calculated as 100%, and the first thermally conductive filler 20 ranges from 31% to 42%, such as 31%, 32%, 33%, 34%, 35%, 36%, 37%, 38%, 39%, 40%, 41%, or 42%. The total volume of the inner filler is calculated as 100%, and the second thermally conductive filler 30 ranges from 54% to 62%, such as 54%, 55%, 56%, 57%, 58%, 59%, 60%, 61%, or 62%. The total volume of the inner filler is calculated as 100%, and the highly dispersible filler 40 accounts for 1% to 15%, such as 1%, 2%, 3%, 4%, 5%, 6%, 7%, 8%, 9%, 10%, 11%, 12%, 13%, 14%, or 15%. In this way, the present invention disperses the largest filler (i.e., the first thermally conductive filler 20 with the largest maximum diameter) into the thermal interface material 200, filling most gaps formed by particles of the first thermally conductive filler 20 with the second thermally conductive filler 30. Subsequently, the highly dispersible filler 40 is introduced to reduce the thermal contact resistance between the first thermally conductive filler 20 and the second thermally conductive filler 30, while facilitating blending among the materials (i.e., the thermally melting material 10, the first thermally conductive filler 20, and the second thermally conductive filler 30), and molding them into the desired shape.

The thickness T of the thermal interface material 200 may be adjusted without compromising its excellent thermal conductivity. In one embodiment, the thickness T of the thermal interface material 200 ranges from 0.05 mm to 0.21 mm, with a thermal resistance ranging from 0.07 cm²·° C./W to 0.5 cm²·° C./W and a thermal conductivity ranging from 3 W/m·K to 81 W/m·K. In one embodiment, the thickness T of the thermal interface material ranges from 0.06 mm to 0.15 mm, with the thermal resistance ranging from 0.08 cm²·° C./W to 0.24 cm²·° C./W and the thermal conductivity ranging from 11.24 W/m. K to 80.08 W/m·K. Furthermore, the present invention tests the weather resistance of the thermal interface material 200 under two test conditions (referred to as “first weather-resistance test” and “second weather-resistance test” hereinafter). The first weather-resistance test includes placing the thermal interface material 200 in an environment at a temperature of 85° C. and a relative humidity of 85% for 500 hours. After the first weather-resistance test, the thermal resistance of the thermal interface material 200 ranges from 0.08 cm²·° C./W to 0.24 cm²·° C./W, and the thermal conductivity of the thermal interface material 200 ranges from 11.24 W/m·K to 80.08 W/m·K. The second weather-resistance test includes placing the thermal interface material 200 in an environment at a temperature of 125° C. for 500 hours. After the second weather-resistance test, the thermal resistance of the thermal interface material 200 ranges from 0.1 cm²·° C./W to 0.31 cm²·° C./W, and the thermal conductivity of the thermal interface material 200 ranges from 5.62 W/m·K to 66.4 W/m·K.

In addition, thermal interface material 200 of the present invention has excellent durability, allowing it to withstand numerous temperature shocks without being damaged. For example, the present invention repeatedly perform a test according to ASTM D5470 on the same thermal interface material 200. For each time, the test applies a pressure of 10 psi and a temperature of 70° C. The number of tests conducted on the material is referred to as its operable time. In other words, the operable time of the thermal interface material 200 is defined as the number of times the thermal interface material 200 can be tested according to ASTM D5470 without being damaged. If the thickness T of the thermal interface material 200 is greater than 0.1 mm, the operable time of it is at least two. If the thickness T of the thermal interface material 200 is greater than 0.15 mm, the operable time of it is at least five.

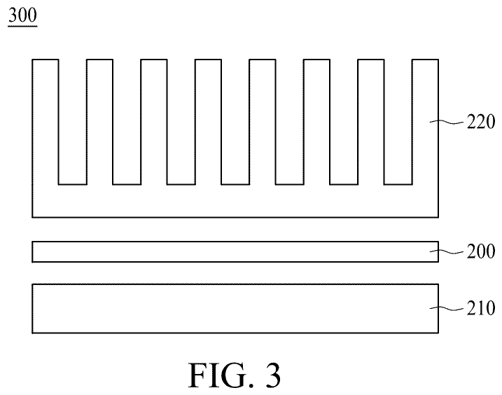

Please refer to FIG. 3. FIG. 3 shows a cross-sectional view of an electronic apparatus 300, with the thermal interface material 200 in accordance with the present invention. The thermal interface material 200 can be adhered to the surface of a heat sink, and then placed on a heat-generating device. The details are described as follows. In FIG. 3, the electronic apparatus 300 includes a heat sink 220, an electronic device, and the thermal interface material 200 as previously mentioned. The heat sink 220 has a front side and a back side opposite to the front side. The heat sink 220 may be a fin-type heat sink, with a plurality of fin structures extending from its front side, while its back side remains substantially smooth. The electronic device 210 has a front side and a back side opposite to the front side. The back side of the electronic device 210 faces the back side of the heat sink 220. It is understood that the surface of the back side of the heat sink 220 is actually uneven when viewed at a microscopic scale, as is the back side of the electronic device 210. If the back side of the heat sink 220 is directly attached to the back side of the electronic device 210, numerous gaps form at their interface, leading to the issue of high thermal contact resistance. However, the aforementioned gaps can be filled with the thermal interface material 200, thereby reducing the thermal contact resistance at the interface. Accordingly, the thermal interface material 200 is disposed between the heat sink 220 and the electronic device 210, while the thermal interface material 200 attaches to the back side of the heat sink 220 and the back side of the electronic device 210.

In order to describe the thermal interface material 200 of the present invention more clearly, the following verification is provided.

TABLE 1
Polymer

| Polymer | Melting point | Melt flow index | Acrylate content |
|---|---|---|---|
| type | (° C.) | (g/10 min) | (wt %) |
| EEA-1 | 49 | 400 | 33 |
| EBA | 69 | 150 | 33 |
| EEA-2 | 67 | 400 | 28 |
| EEA-3 | 61 | 400 | 33 |

TABLE 2
Inner Filler

| Filler type | d(0.1) | | d(0.5) | | d(0.9) | | d(max) | |
|---|---|---|---|---|---|---|---|---|
| AlN-1 | 0.60 | μm | 1.40 | μm | 3.20 | μm | 8.70 | μm |
| AlN-2 | 1.79 | μm | 3.70 | μm | 7.01 | μm | 11.42 | μm |
| AlN-3 | 0.54 | μm | 2.10 | μm | 5.90 | μm | 15.13 | μm |
| AlN-4 | 2.05 | μm | 14.75 | μm | 30.83 | μm | 45.70 | μm |
| AlN-5 | 31.21 | μm | 48.88 | μm | 75.83 | μm | 104.80 | μm |
| Al₂O₃ | 1.29 | μm | 5.14 | μm | 11.44 | μm | 18.38 | μm |
| TiO₂ | 0.38 | μm | 0.55 | μm | 0.84 | μm | 1.26 | μm |

TABLE 3
Volume Percentage between Polymer and Inner Filler

| Group | Polymer (vol %) | Inner filler (vol %) |
|---|---|---|
| E1 | 28 | 72 |
| E2 | 31 | 69 |
| E3 | 31 | 69 |
| E4 | 31 | 69 |
| E5 | 31 | 69 |
| E6 | 31 | 69 |
| E7 | 31 | 69 |
| E8 | 31 | 69 |
| C1 | 35 | 65 |
| C2 | 33 | 67 |
| C3 | 29 | 71 |

In the experiment, the thermal interface material 200 consists of a polymer and an inner filler.

Table 1 lists the polymers (i.e., the aforementioned PMM) available for the present invention. There are three types of ethylene ethyl acrylate, referred to as EEA-1, EEA-2, and EEA-3, respectively; and one type of ethylene butyl acrylate, referred to as EBA. These four polymers belong to the type of olefin-acrylate copolymer as previously mentioned, with the melting point ranging from 49° C. to 69° C. and the melt flow index ranging from 150 g/10 min to 400 g/10 min. These polymers can be used in the present invention. Depending on the requirements, the melt flow index can be adjusted through various polymerization methods. For example, the melt flow index may range from 110 g/10 min to 400 g/10 min, and the same or similar technical effects can be achieved. Other alternative values of the melt flow index has been discussed above, and the details are not described herein.

Table 2 lists the fillers available for the present invention, which are five aluminum nitrides (i.e., AlN-1, AlN-2, AlN-3, AlN-4, and AlN-5), aluminum oxide (Al₂O₃), and titanium dioxide (TiO₂). Each filler consists of a plurality of particles, having a specific diameter distribution. The distribution of particle sizes is measured by a particle size analyzer (commercialized brand name Malvern Mastersizer 2000). “d” stands for “distribution of particle size”, and the number within brackets after “d” refers to the proportion of the particles. The total number of particles is calculated as 1, so 0.1, 0.5 and 0.9 refer to 10%, 50% and 90%, respectively. For example, d(0.1) means that 10% of particles are smaller than the values of d(0.1) listed in Table 3. d(0.5) and d(0.9) are interpreted in the same way. As for d(max), it refers to the maximum particle diameter present among all the particles. In addition, d(0.5) stands for the middle value of particle size distribution, that is, the median diameter. As previously mentioned, the maximum diameter serves as the criterion for determining filler ratios in the present invention. Considering the measurement error and the permissible error tolerance, the maximum diameter may vary within a specific range, and the same or similar technical effects can be achieved. For example, d(max) of AlN-1 may range from 8 μm to 10 μm; d(max) of AlN-2 may range from 9 μm to 13 μm; d(max) of AlN-3 may range from 14 μm to 17 μm; d(max) of AlN-4 may range from 40 μm to 50 μm; d(max) of AlN-5 may range from 90 μm to 110 μm; d(max) of aluminum oxide may range from 17 μm to 19 μm; and d(max) of titanium dioxide may range from 0.8 μm to 1.5 μm. Other alternatives has been discussed previously and are not detailed herein. AlN-1, AlN-2, AlN-3, AlN-4, AlN-5, and aluminum oxide are the thermally conductive fillers commonly used. Titanium dioxide serves as the highly dispersible filler 40 as previously mentioned. Specifically, titanium dioxide of the present invention is a highly purified rutile TiO₂, with a purity of 99 wt %.

Table 3 shows the composition of embodiments E1 to E8 and comparative examples C1 to C3. In practical use, the polymer may consist of one or more olefin-acrylate copolymers, and the inner filler may consist of one or more fillers. In the embodiments E1 to E8 and the comparative examples C1 to C3, each group has a similar proportion between the polymer and the inner filler. The total volume of the thermal interface material 200 is calculated as 100%, with the polymer accounting for about 28% to about 35% and the inner filler accounting for about 65% to about 72%. In order to investigate the impact of maximum diameter and dispersant on the device's performance, the difference between embodiments and comparative examples lies in the addition of titanium dioxide (as shown in Table 4 below). Accordingly, the polymers of the embodiments E1 to E8 and the comparative examples C1 to C3 consist of ethylene butyl acrylate (EBA). The inner filler in each group of the embodiments E1 to E8 and the comparative examples C1 to C3 consists of various fillers.

TABLE 4
Composition of Inner Filler and Performance of TIM

| | | | | | | | | Thermal | Thermal |
|---|---|---|---|---|---|---|---|---|---|
| | AlN-1 | AlN-2 | AlN-3 | AlN-4 | AlN-5 | TiO₂ | Al₂O₃ | resistance | conductivity |
| Group | (vol %) | (vol %) | (vol %) | (vol %) | (vol %) | (vol %) | (vol %) | (cm² · ° C./W) | (W/m · K) |
| E1 | | | 85 | | | 15 | | 0.73 | 1.76 |
| E2 | | | 87 | | | 13 | | 0.57 | 2.15 |
| E3 | | | 93 | | | 7 | | 0.40 | 3.10 |
| E4 | 37 | 59 | | | | 4 | | 0.21 | 7.75 |
| E5 | 37 | | 59 | | | 4 | | 0.29 | 3.69 |
| E6 | 37 | | | 59 | | 4 | | 0.12 | 52.00 |
| E7 | 36 | | | | 60 | 4 | | 0.43 | 3.07 |
| E8 | 37 | | | | | 4 | 59 | 0.32 | 4.92 |
| C1 | | 8 | 92 | | | | | 0.53 | 2.46 |
| C2 | 40 | 60 | | | | | | 0.24 | 5.90 |
| C3 | | 40 | 60 | | | | | 0.40 | 3.10 |

As described above, each inner filler in the embodiments E1 to E8 includes a highly dispersible filler (i.e., TiO₂), whereas each of the comparative examples C1 to C3 does not. In the embodiments E1 to E3, the inner filler consists of one thermally conductive filler (i.e., AlN-3) and one highly dispersible filler (i.e., TiO₂). In the embodiments E4 to E8, the inner filler consists of two thermally conductive fillers (i.e., AlN-1/AlN-2, AlN-1/AlN-3, AlN-1/AlN-4, AlN-1/AlN-5, or AlN-1/Al₂O₃) and one highly dispersible filler (i.e., TiO₂). In other words, the inner filler may include one or more thermally conductive fillers and a highly dispersible filler according to the embodiments E1 to E8, wherein the thermally conductive filler accounts for 85% to 96%, while the highly dispersible filler accounts for 4% to 15%. In contrast, in the comparative examples C1 to C3, each inner filler consists of two thermally conductive fillers, with no highly dispersible filler included.

The manufacturing process of the thermal interface material is described below. According to the composition shown in Table 3 and Table 4, materials are prepared and put into HAAKE twin screw blender for blending. The blending temperature is 160° C., the time for pre-mixing is 3 minutes, and the blending time is 15 minutes. A thermally conductive composite can be obtained after blending, and is pressed into a sheet with a thickness of 0.1 mm by a hot press machine at a temperature of 160° C. This sheet is subsequently cut into pieces, each of which is a thermal interface material with dimensions of 3 cm×3 cm. Two copper foils are disposed on the top and bottom surfaces of the thermal interface material, each having the same dimensions as the thermal interface material. This forms a three-layer structure used in the following tests. The three-layer structure more accurately represents the actual application of the thermal interface material, and thus the data measured in the following tests will more closely reflect the actual data in practical use. Additionally, it is worth mentioning that in the comparative examples C1 to C3, any thermally conductive composite (which lacks TiO₂) is difficult to shape during blending. That is, the thermally conductive composites of the comparative examples C1 to C3 tend to disintegrate easily and do not form stable agglomerates. In the embodiments E1 to E8, the percentage of TiO₂ may range from 1% to 15% depending on the requirements.

The thermal resistance and the thermal conductivity of the thermal interface material are measured according to the standard test method of ASTM D5470. For each time, the test applies a pressure of 10 psi and a temperature of 70° C. In the embodiments E1 to E3, the thermal resistance ranges from 0.4 cm²·° C./W to 0.73 cm²·° C./W, and the thermal conductivity ranges from 1.76 W/m·K to 3.1 W/m·K. In the embodiments E4 to E8, the thermal resistance ranges from 0.12 cm²·° C./W to 0.43 cm²·° C./W, and the thermal conductivity ranges from 3.07 W/m·K to 52 W/m·K. In the comparative examples C1 to C3, the thermal resistance ranges from 0.24 cm²·° C./W to 0.53 cm²·° C./W, and the thermal conductivity ranges from 2.46 W/m·K to 5.9 W/m·K. From the embodiments E1 to E3, it can be observed that there is no significant improvement in the combination of one thermally conductive filler and one highly dispersible filler. Specifically, the thermal resistance significantly increases as the ratio of titanium dioxide reaches 15% in the embodiment E1. When the thermal interface material is filled with an excessive amount of titanium dioxide (i.e., above 15%) which has low thermal conductivity, much of the heat would be conducted through a less efficient pathway, resulting in excessively high thermal resistance (not shown in Table 4), which does not meet practical industrial requirements. However, the thermal interface material exhibits lower thermal resistance and higher thermal conductivity when its inner filler consists of two thermally conductive fillers and one highly dispersible filler, as shown in the embodiments E4 to E8. It is noted that the embodiment E6 exhibits the best thermally conductive characteristics (i.e., the lowest thermal resistance and the highest thermal conductivity), as verified by three repeated tests.

In this test, the maximum stress that a material can bear before breaking (referred to as tensile strength) is measured using an ALGOL tensile testing machine (model: JSV-500D). The tensile strengths of the embodiments E1 to E8 are 0.735 kg, 1.11 kg, 1.05 kg, 1.145 kg, 1.06 kg, 0.98 kg, 1.07 kg, and 1.15 kg, respectively. The tensile strengths of the comparative examples C1 to C3 are 1.22 kg, 1.12 kg, and 0.802 kg, respectively. That is, in the embodiments E1 to E8, the tensile strength ranges from 0.7 kg to 1.2 kg, while in the comparative examples C1 to C3, the tensile strength ranges from 0.8 kg to 1.2 kg. The above range of the embodiments is similar to that of the comparative examples. This suggests that the maximum diameter and the ratio of titanium dioxide specified by the present invention do not cause adverse effects on tensile strength, and the thermal interface material can still maintain good structural strength.

TABLE 5
Performance of TIM with Different Thicknesses (1)

| | | Thermal | Thermal | |
|---|---|---|---|---|
| | Thickness | resistance | conductivity | Operable |
| Group | (mm) | (cm² · ° C./W) | (W/m · K) | time |
| E6-1 | 0.06 | 0.08 | 80.08 | 1 |
| E6-2 | 0.10 | 0.12 | 52.70 | 3 |
| E6-3 | 0.15 | 0.24 | 11.24 | 5 |
| E6-4 | 0.20 | 0.47 | 3.75 | 6 |

Due to significant improvements in thermal resistance and thermal conductivity of the embodiment E6, it can be further be verified across various thicknesses. By adjusting the pressure of hot press machine, the thermal interface material of the embodiment E6 can be pressed into various thicknesses, such as 0.06 mm, 0.1 mm, 0.15 mm, and 0.2 mm, corresponding to embodiments E6-1, E6-2, E6-3, and E6-4, respectively. In each test, since a pressure of 10 psi and a temperature of 70° C. are applied to the thermal interface material, it is not possible to test the same material an unlimited number of times. On the contrary, the thermal interface material deforms or even breaks as the number of tests increases. In Table 5, the operable time is defined as the number of times the same thermal interface material can be tested without being damaged.

In the embodiments E6-1 to E6-4, the thermal resistance ranges from 0.08 cm²·° C./W to 0.47 cm²·° C./W, and the thermal conductivity ranges from 3.75 W/m·K to 80.08 W/m·K. Compared with all the embodiments in Table 3, the embodiment E6-4 still exhibits low thermal resistance and high thermal conductivity even though its thickness is twice as much as theirs. More importantly, the operable time of the embodiment E6-4 is six. In other words, in order to enhance the durability of the thermal interface material (i.e., the operable time), the embodiment E6 can be made much thicker without compromising its performance in thermal resistance and thermal conductivity. Considering the measurement error and the permissible error tolerance, the thickness of the embodiments E6-1 to E6-4 may range from 0.05 mm to 0.21 mm, and the same or similar technical effects can be achieved.

TABLE 6
Performance of TIM with Different Thicknesses (2)

| | | | | | | | | Insulation |
|---|---|---|---|---|---|---|---|---|
| | | | | | | | | strength |
| | Thickness | TR | TC | TR-1 | TC-1 | TR-2 | TC-2 | AC |
| Group | (mm) | (cm² · ° C./W) | (W/m · K) | (cm² · ° C./W) | (W/m · K) | (cm² · ° C./W) | (W/m · K) | (kV/mm) |
| E6-1 | 0.06 | 0.08 | 80.08 | 0.08 | 80.08 | 0.1 | 66.4 | >30 |
| E6-2 | 0.10 | 0.12 | 52.70 | 0.12 | 52.70 | 0.15 | 49.29 | >30 |
| E6-3 | 0.15 | 0.24 | 11.24 | 0.24 | 11.24 | 0.31 | 5.62 | >30 |

The present invention further tests the weather resistance of the embodiments E6-1 to E6-3. TR (i.e., thermal resistance) and TC (i.e., thermal conductivity) refer to the thermal resistance and the thermal conductivity of the thermal interface material without undergoing any thermal treatment and humidity treatment. TR-1 and TC-1 refer to the thermal resistance and the thermal conductivity of the thermal interface material after being exposed to an environment at a temperature of 85° C. and a relative humidity of 85% for 500 hours (i.e., after the first weather-resistance test as previously mentioned). TR-2 and TC-2 refer to the thermal resistance and the thermal conductivity of the thermal interface material after being exposed to an environment at a temperature of 125° C. for 500 hours (i.e., after the second weather-resistance test as previously mentioned). In Table 6, it is observed that the embodiments E6-1 to E6-3 can still exhibit low thermal resistance and high thermal conductivity even under different stresses. After the first weather-resistance test, the thermal resistance of the embodiments E6-1 to E6-3 ranges from 0.08 cm²·° C./W to 0.24 cm²·° C./W, and the thermal conductivity of the embodiments E6-1 to E6-3 ranges from 11.24 W/m·K to 80.08 W/m·K. After the second weather-resistance test, the thermal resistance of the embodiments E6-1 to E6-3 ranges from 0.1 cm²·° C./W to 0.31 cm²·° C./W, and the thermal conductivity of the embodiments E6-1 to E6-3 ranges from 5.62 W/m·K to 66.4 W/m·K. From the above, the thermal interface material of the present invention can maintain consistent performance under conditions of 85° C. and 85% relative humidity. At the high temperature of 125° C., it exhibits merely slight changes in thermal resistance and thermal conductivity. In addition, in the embodiments E6-1 to E6-3, the insulation strength under alternating current (AC) reaches above 30 kV/mm, demonstrating excellent voltage endurance capability.

The above-described embodiments of the present invention are intended to be illustrative only. Numerous alternative embodiments may be devised by persons skilled in the art without departing from the scope of the following claims.

What is claimed is:

1. A thermal interface material, comprising:
a thermally melting material comprising an olefin-acrylate copolymer, wherein:
the olefin-acrylate copolymer has a melt flow index higher than 110 g/10 min; and
the total volume of the thermal interface material is calculated as 100%, and the olefin-acrylate copolymer accounts for 25% to 35%; and
an inner filler having a plurality of thermally conductive fillers and a highly dispersible filler, wherein the total volume of the thermal interface material is calculated as 100%, and the thermally conductive fillers and the highly dispersible filler together account for 65% to 75%.

2. The thermal interface material of claim 1, wherein the olefin-acrylate copolymer has a melting point lower than 70° C. and the melt flow index ranging from 110 g/10 min to 500 g/10 min, and the olefin-acrylate copolymer is represented by a formula (I): 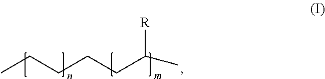
wherein:
R is selected from the group consisting of COOCH₃, COOC₂H₅, COOC₄H₉, and COOC₆H₁₃;
m ranges from 500 to 3000, and n ranges from 300 to 2000; and
m is larger than n.

3. The thermal interface material of claim 1, wherein:
the total volume of the inner filler is calculated as 100%, and the highly dispersible filler accounts for 1% to 15%; and
the highly dispersible filler has a maximum diameter smaller than 1.5 μm.

4. The thermal interface material of claim 3, wherein the highly dispersible filler comprises a titanium-containing oxide selected from the group consisting of rutile titanium dioxide and unavoidable impurities, wherein the total weight of the titanium-containing oxide is calculated as 100%, and the rutile titanium dioxide accounts for over 90%.

5. The thermal interface material of claim 1, wherein the thermally conductive fillers comprise a first thermally conductive filler and a second thermally conductive filler, wherein:
the first thermally conductive filler has a maximum diameter smaller than 10 μm; and
the second thermally conductive filler has a maximum diameter smaller than 50 μm.

6. The thermal interface material of claim 5, wherein:
the maximum diameter of the first thermally conductive filler ranges from 8 μm to 10 μm, wherein the total volume of the inner filler is calculated as 100%, and the first thermally conductive filler ranges from 31% to 42%; and
the maximum diameter of the second thermally conductive filler ranges from 40 μm to 50 μm, wherein the total volume of the inner filler is calculated as 100%, and the second thermally conductive filler ranges from 54% to 62%.

7. The thermal interface material of claim 6, wherein the first thermally conductive filler and the second thermally conductive filler are selected from the group consisting of aluminum nitride, aluminum oxide, boron nitride, silicon carbide, and magnesium oxide.

8. The thermal interface material of claim 1, wherein the thermally conductive fillers have maximum diameters smaller than 50 μm, and the highly dispersible filler has a maximum diameter smaller than 1.5 μm, wherein the thermal interface material has a thickness ranging from 0.05 mm to 0.21 mm, with a thermal resistance ranging from 0.07 cm²·° C./W to 0.5 cm²·° C./W and a thermal conductivity ranging from 3 W/m·K to 81 W/m·K.

9. The thermal interface material of claim 8, wherein the thickness of the thermal interface material ranges from 0.06 mm to 0.15 mm, with the thermal resistance ranging from 0.08 cm²·° C./W to 0.24 cm²·° C./W and the thermal conductivity ranging from 11.24 W/m·K to 80.08 W/m·K.

10. The thermal interface material of claim 1, wherein the thermal interface material has a thermal resistance ranging from 0.08 cm²·° C./W to 0.24 cm²·° C./W and a thermal conductivity ranging from 11.24 W/m·K to 80.08 W/m·K after a first weather-resistance test, wherein the first weather-resistance test comprises placing the thermal interface material at a temperature of 85° C. and a relative humidity of 85% for 500 hours.

11. The thermal interface material of claim 1, wherein the thermal interface material has a thermal resistance ranging from 0.1 cm²·° C./W to 0.31 cm²·° C./W and a thermal conductivity ranging from 5.62 W/m·K to 66.4 W/m·K after a second weather-resistance test, wherein the second weather-resistance test comprises placing the thermal interface material at a temperature of 125° C. for 500 hours.

12. The thermal interface material of claim 1, wherein the thermal interface material has a thickness greater than 0.1 mm, and an operable time for the thermal interface material is at least two, wherein the operable time is defined as the number of times the thermal interface material can be tested according to ASTM D5470 without being damaged.

13. The thermal interface material of claim 12, wherein the thickness of the thermal interface material is greater than 0.15 mm, and the operable time for the thermal interface material is at least five.

14. An electronic apparatus, comprising:
a heat sink having a front side and a back side opposite to the front side;
an electronic device having a front side and a back side opposite to the front side, wherein the back side of the electronic device faces the back side of the heat sink; and
a thermal interface material of claim 1 disposed between the heat sink and the electronic device, wherein the thermal interface material attaches to the back side of the heat sink and the back side of the electronic device.

15. The electronic apparatus of claim 14, wherein the olefin-acrylate copolymer of the thermal interface material has a melting point lower than 70° C. and the melt flow index ranging from 110 g/10 min to 500 g/10 min, and the olefin-acrylate copolymer is represented by a formula (I): 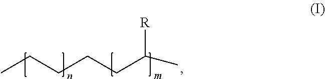
wherein:
R is selected from the group consisting of COOCH₃, COOC₂H₅, COOC₄H₉, and COOC₆H₁₃;
m ranges from 500 to 3000, and n ranges from 300 to 2000; and
m is larger than n.

16. The electronic apparatus of claim 14, wherein in the thermal interface material:
the highly dispersible filler comprises a titanium-containing oxide selected from the group consisting of rutile titanium dioxide and unavoidable impurities, wherein the total weight of the titanium-containing oxide is calculated as 100%, and the rutile titanium dioxide accounts for over 90%;
the total volume of the inner filler is calculated as 100%, and the highly dispersible filler accounts for 1% to 15%; and
the highly dispersible filler has a maximum diameter smaller than 1.5 μm.

17. The electronic apparatus of claim 14, wherein the thermally conductive fillers of the thermal interface material comprise a first thermally conductive filler and a second thermally conductive filler, wherein:
a maximum diameter of the first thermally conductive filler ranges from 8 μm to 10 μm, wherein the total volume of the inner filler is calculated as 100%, and the first thermally conductive filler ranges from 31% to 42%; and
a maximum diameter of the second thermally conductive filler ranges from 40 μm to 50 μm, wherein the total volume of the inner filler is calculated as 100%, and the second thermally conductive filler ranges from 54% to 62%.

18. The electronic apparatus of claim 17, wherein the first thermally conductive filler and the second thermally conductive filler are selected from the group consisting of aluminum nitride, aluminum oxide, boron nitride, silicon carbide, and magnesium oxide.

19. The electronic apparatus of claim 14, wherein in the thermal interface material, the thermally conductive fillers have maximum diameters smaller than 50 μm, and the highly dispersible filler has a maximum diameter smaller than 1.5 μm, wherein the thermal interface material has a thickness ranging from 0.05 mm to 0.21 mm, with a thermal resistance ranging from 0.07 cm²·° C./W to 0.5 cm²·° C./W and a thermal conductivity ranging from 3 W/m·K to 81 W/m·K.

20. The electronic apparatus of claim 14, wherein the thermal interface material has a thickness greater than 0.1 mm, and an operable time for the thermal interface material is at least two, wherein the operable time is defined as the number of times the thermal interface material can be tested according to ASTM D5470 without being damaged.
